(19) United States
(12) Patent Application Publication
(10) Pub. No.: US 2010/0001320 A1
(43) Pub. Date: Jan. 7, 2010

(54) THIN FILM TRANSISTOR ARRAY DEVICES

(75) Inventor: FRANK W. ROHLFING, CAMBRIDGE (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/722,882

(22) PCT Filed: Jan. 3, 2006
(86) PCT No.: PCT/IB06/50011

§ 371 Date: Jun. 27, 2007

(30) Foreign Application Priority Data
Jan. 6, 2005 (GB) 0500115.1

(51) Int. Cl. H01L 27/12

(52) U.S. Cl. 257/204; 257/E27.111

(57) ABSTRACT

A transistor circuit for an array device comprises a plurality of thin film transistors electrically connected in parallel and provided on a common substrate. The transistors are arranged on the substrate as at least two rows (20ᵢ, 2O₂, 2O₃) of transistors, and the source lines (30) of the transistors in the first and second rows have different widths and the drain lines (32) of the transistors in the first and second rows have different widths. All sources (30) are connected together and all drains (32) are connected together, and a source connection is provided to an end portion of the wider source lines and a drain connection is provided to an end portion of the wider drain lines. This provide a source and drain layout that reduces layout area and pitch of wide channel TFTs, whilst preventing degradation in the source and drain terminals/lines due to high current densities. The layout essentially comprises groups of small parallel TFTs, which are in turn connected in parallel.

This invention relates to devices using arrays of thin film transistors, particularly devices in which the space available requires a small pitch between adjacent transistors or transistor circuits.

Array devices of this type may have a two dimensional array of transistors (or transistor-based circuits) or a one dimensional array (line) of such transistors or transistor circuits. The latter case may for example apply to circuits arranged along an edge of a two dimensional pixel array for providing control signals or pixel read/write data.

Many low-temperature poly-crystalline silicon (LTPS) circuits require the use of arrays of thin-film transistors (TFT) with very wide channels to drive large loads. Example of such circuits are the column driver output stages in active-matrix liquid-crystal displays (AMLCD), TFTs in charge-pump circuits for AMLCDs or LTPS circuits in which TFTs are used to drive high-power resistive elements.

An example of the latter type of application is a thermal inkjet print head. In this case, thin-film resistors are used to heat small volumes of ink that are then forced through tiny nozzle arrays as a result of thermal expansion. The resistors are switched via TFTs, and because of the high power required, the TFTs have to have a very wide channel in order to provide sufficient current. This is particularly the case for thermal inkjet print heads that are based on LTPS (low temperature polysilicon) as opposed to conventional silicon wafer technology, because a wider channel is necessary in LTPS technology to compensate for the reduced mobility, higher threshold voltage and longer channels.

The switching TFTs in LTPS-based thermal inkjet print heads typically require channel widths of the order of a few hundred micrometres to several centimetres. Because of their size it is difficult to fit them into a circuit and to connect them to peripheral electronics. For most printing applications, the print nozzle pitch is of the order of ten to several hundred micrometres, and the large driving transistor array has to be adapted to this pitch.

In a linear array of transistor circuits, there may be sufficient space perpendicular to the pitch direction, and this can be used to accommodate a large transistor channel width. However, this alone does not necessarily enable the desired transistor current drive characteristics to be achieved.

Most LTPS array processes only use two metal layers, one functions as the gate metal and the other one connects to the poly-Si source and drain regions and functions as interconnect metal. In a two-metal process, routing across TFTs is not possible. This would require a third metal, but the disadvantage of introducing a third metal layer for routing purposes is that it would increase process complexity and costs and reduces yield. Consequently, in two-metal processes, the current density in the source and drain lines of wide-channel TFTs can become very high when it is necessary to adapt them to a small pitch. The high current density can lead to degradation due to self-heating or due to electromigration. For a given pitch, there is a maximum channel width which cannot be exceeded as electromigration or self-heating would destroy the TFT.

Furthermore, for very wide channels, the series resistance of the source and drain supply lines becomes comparable to the TFT on resistance.

According to the invention, there is provided an array device comprising an array of transistor circuits comprising at least one row of transistor circuits, wherein each transistor circuit comprises a plurality of thin film transistors electrically connected in parallel and provided on a common substrate, the transistors being arranged on the substrate as at least two rows of transistors, wherein the source lines of the transistors in the first and second rows have different widths and the drain lines of the transistors in the first and second rows have different widths, all sources being connected together and all drains being connected together, and wherein a source connection is provided to an end portion of the wider source lines and a drain connection is provided to an end portion of the wider drain lines.

This layout provide a source and drain layout that reduces layout area and pitch of wide channel TFTs, whilst preventing degradation in the source and drain terminals/lines due to high current densities. The layout essentially comprises groups of small parallel TFTs, which are in turn connected in parallel.

Because the source and drain lines have different widths, and the connection is made to the wide lines, the width of the source and drain lines is matched to the current density experienced in that part of the circuit layout. By optimising the line widths in this way across different areas of the substrate, the use of substrate area is improved. For example, more transistors can be fitted into a region where the transistors have narrower source and drain terminals.

The layout of the invention can prevent self-heating and electromigration-induced TFT degradation as a result of lower current densities in the source and drain lines. TFTs with wider channels can be adapted to a particular array pitch, or, alternatively, for a fixed channel width, the array pitch can be reduced.

For LTPS thermal inkjet printing, the former enables higher power per nozzle, which improves contrast ratio and printing speed (throughput), whilst the latter translates into improved image quality as a reduction of the nozzle pitch allows printing at higher resolution.

The more effective use of the layout area can also reduce the circuit costs.

The use of the proposed layouts in the column driver output stages of AMLCDs enables a finer pixel pitch and reduced layout area, the former improves the optical image quality and the latter gives smaller display margins and reduces costs.

The transistors in one row may each have the same channel length and channel width, the channel width being perpendicular to the row direction.

In one type of arrangement, one of the first and second rows of transistors has narrower source and drain lines than the other of the first and second rows of transistors. There can then be more transistors in the one row than in the other row, for example twice as many.

The transistors in the one row can have a first channel width and a first channel length, and the transistors in the other row have a second, greater channel width and the same, first channel length. In this way, the channel width for each row of transistors can be optimised, in particular so that at the end of the channel width facing the connection, the current density in the source or drain lines reaches a predetermined amount, which is close to the maximum permitted current density taking into account the source and drain widths.

The source and drain connections are both at the top or bottom of the transistor circuit in this configuration, and a pyramid type structure results.

For example, each circuit can comprises M rows of transistors, the m^{th} row having k×2^{(m-1)} transistors, for example three rows of transistors with 1, 2 and 4 transistors.

Two of these configurations can be provided back-to back, so that each circuit comprises 2M rows of transistors, a top M rows in which the m^{th} row has k×2^{(m-1)} transistors, and a bottom M rows in which in which the m^{th} row has k×2^{(M-m)} transistors, for example six rows of transistors with 1, 2, 4, 4, 2 and 1 transistors. In this case, the transistor circuit is provided with source and drain connections at the top and bottom.

In an alternative configuration, the transistors of one of the first and second rows of transistors can have a wider source and a narrower drain than the transistors of the other of the first and second rows of transistors. This defines an arrangement in which the source and drain lines taper in width in opposite senses, and can thus occupy the same space in combination at any row in the structure. There may then be the same number of transistors in each row, for example two rows of four transistors.

The transistors in each row can then have the same channel width and channel length.

This configuration requires one of the source and drain connections to be at the top of the transistor circuit and the other of the source and drain connections to be at the bottom of the transistor circuit.

Instead of all rows having the same number of transistors, a top and bottom row of transistors may have the same number (n) transistors, and one or more middle rows of transistors may have 2n transistors, for example a top and bottom row of 2 transistors and two middle rows of 4 transistors.

The transistors in the middle rows can have the same channel length but shorter channel width than the transistors in the top and bottom rows.

In all embodiments, the channel widths of the transistors in any row are the same, and the channel width is selected such to provide a maximum current density in the source or drain line taking into account the source and drain line widths for the transistors in the row.

The circuit can occupy a substantially rectangular substrate area, and the width of the rectangle is selected in dependence on the available pitch between circuits. The width of the rectangle can be in the range 20-200 μm, and the height (corresponding to the combined channel widths) can be much greater, for example of the order of centimeters.

The invention can be applied for example to an ink jet print head, wherein each circuit is for controlling an ink jet print head print nozzle.

The transistor circuits can be fabricated using a two-metal layer thin film process.

Examples of the invention will now be described in detail with reference to the accompanying drawings, in which:

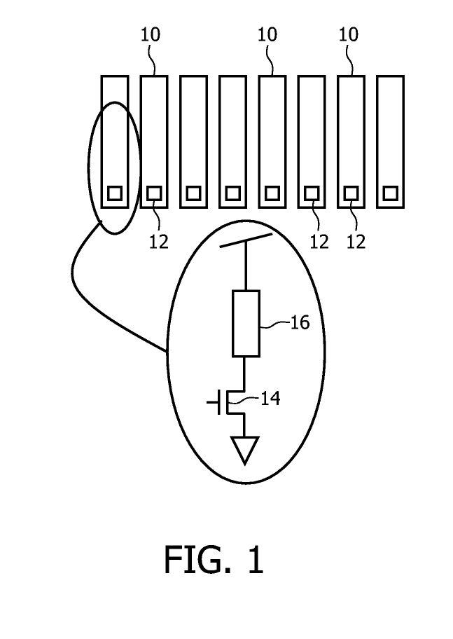

FIG. 1 shows a known ink jet print head layout;

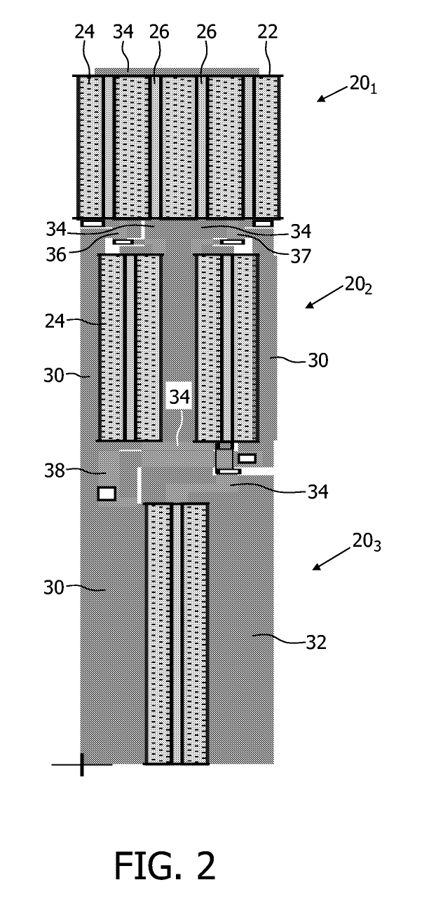

FIG. 2 shows a first example of transistor circuit layout of the invention, for example for controlling one of the ink jet print head nozzles of the device of FIG. 1;

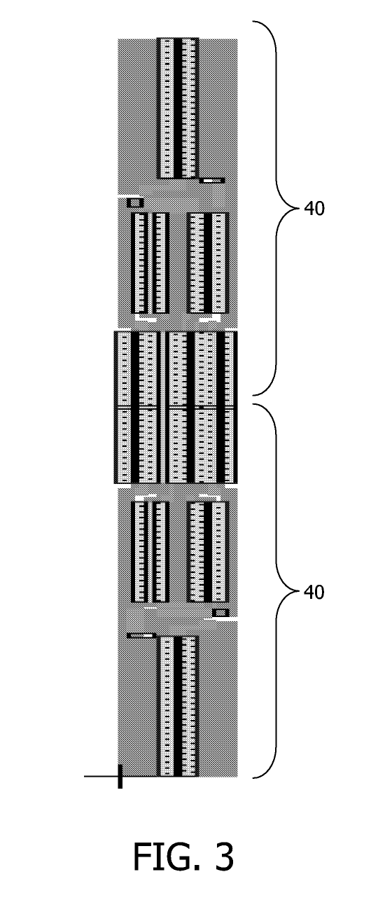

FIG. 3 shows a second example of transistor circuit layout of the invention;

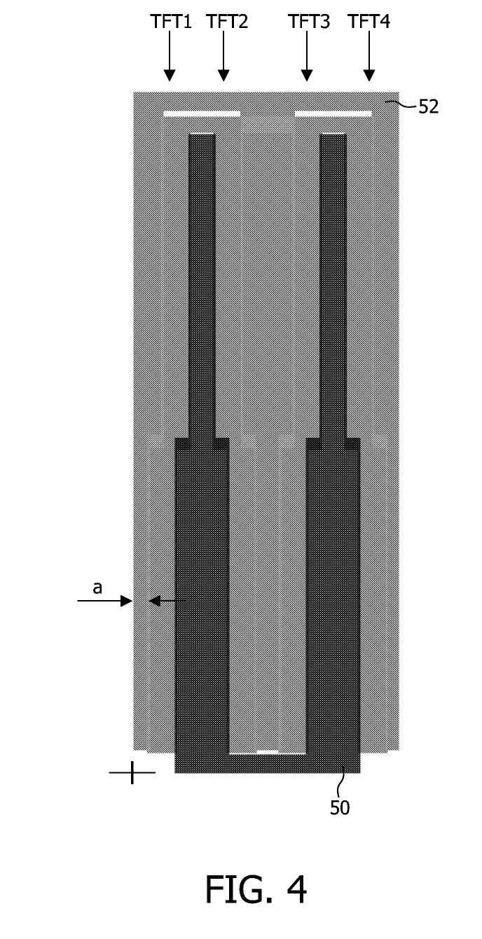

FIG. 4 shows a third example of transistor circuit layout of the invention;

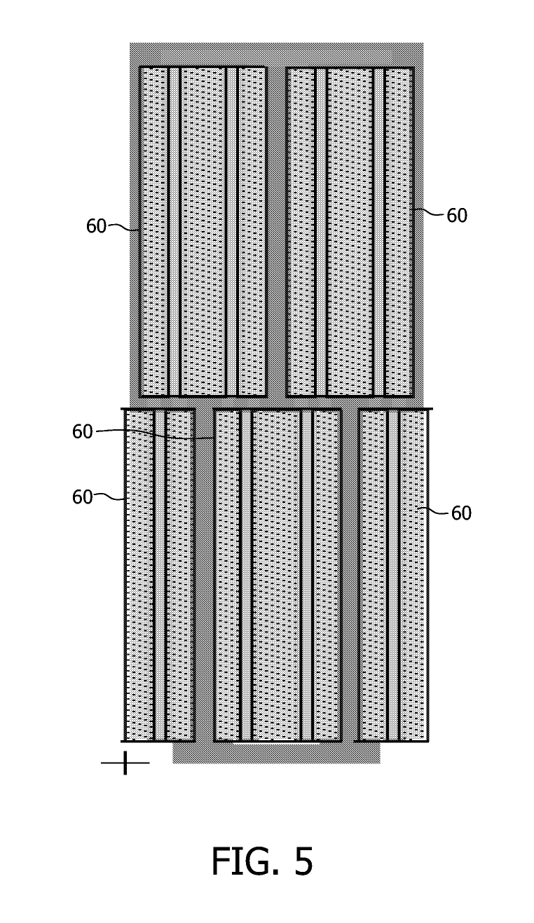

FIG. 5 shows the third example in more detail; and

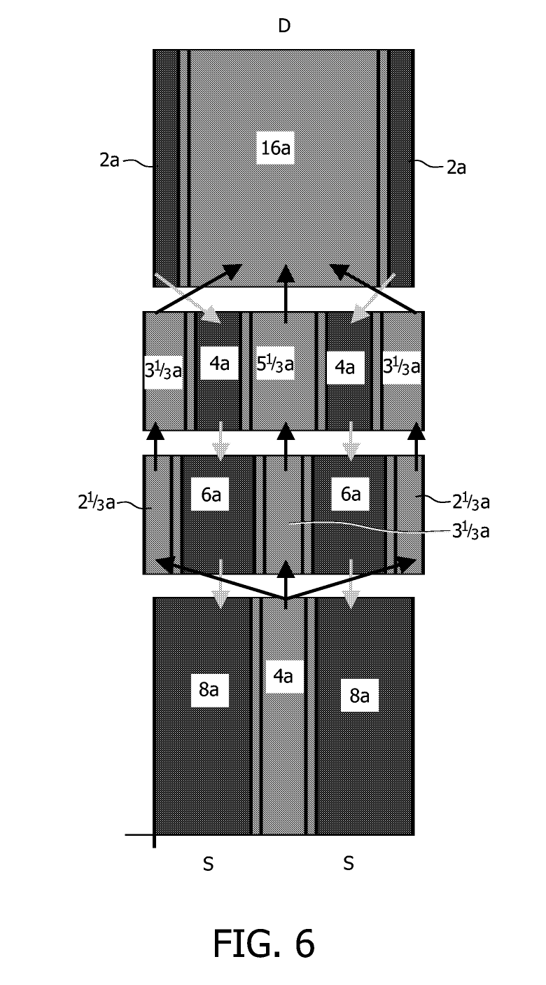

FIG. 6 shows a fourth example of transistor circuit layout of the invention.

This invention relates to transistor circuit layouts, in which wide-channel TFTs are required, and which are needed to be adapted to a small array pitch. The need for a small array pitch arises in many different devices, and this invention can be applied to any device formed as an array of thin film transistor circuits.

FIG. 1 shows schematically an ink jet print head, comprising a linear array of print head circuits 10, each having a printer nozzle 12. FIG. 1 shows that each print head circuit conventionally comprises a thin film transistor 14 in series with a heater element 16. The heater element heats a chamber which is used to cause vaporization of the ink in the nozzle, and cause ejection of a drop of ink.

The pitch between nozzles in this example is typically 20-200 μm, for example 42 μm. The transistor channel width is typically orientated perpendicularly to the pitch, and the smaller channel length is in the direction of the pitch. The small pitch imposes limitations on the width of the tracks defining the source and drain lines and terminals. These limitations affect the breakdown characteristics, and therefore the current carrying capabilities of the transistors. Although a significant space may be available for the channel width (perpendicular to the pitch), difficulties arise in designing transistors with the required characteristics.

The invention provides a transistor circuit which can fit into a rectangular substrate area, and has multiple thin film transistors electrically connected in parallel. The transistors are arranged on the substrate as rows with different dimension source and drain lines (in particular the tracks that define the source and drain terminals and the conducting paths to the edge of the substrate where the source and drains are connected to external signals), in such a way that the use of substrate area is optimised with respect to the current carrying capabilities.

FIGS. 2 to 5 show examples of the invention. The width has been enlarged to enable the details to be seen, and it should be appreciated that the Figures are therefore not accurate. For example, vias shown in FIG. 2 are in fact square, but have been stretched widthways.

FIG. 2 illustrates a first example of circuit layout of the invention in the form of a pyramid-type TFT layout.

In this example, there are three rows 20₁, 20₂, 20₃ of transistors. In the top row, there is a continuous semiconductor region 22, and the transistors are packed as closely together as possible without breaking design rules. Adjacent TFTs share the same source and drain contacts. There are four transistors in the top row 20₁, and the highly doped semiconductor regions 24 are shown hatched, whereas the channels 26 (which are of course aligned with the gates) are shown not hatched.

The close packing of these transistors means they must have narrow source and drain terminals and lines. The sources of all transistors are connected together, and the drains of all transistors are connected together.

The second row 20₂ has two transistors, and the third row 20₃ has one transistor. All transistors have the same channel length, but different rows have different channel widths (i.e. row height).

The less dense packing in the second row allows wider source and drain lines, and the even less dense packing in the third row allows even wider source and drain lines.

The source line is shown as 30 and the drain line as 32, and external connections are made to these lines where they are widest, namely at the bottom of the layout shown in FIG. 2.

The gate terminal is at the top, and the gate line is shown as 34.

The layout is approximately rectangular, and the width represents the pitch of the TFT circuits. Following the source and drain lines downwardly towards the terminals at the bottom, the current density that is present in these lines increases (because there is accumulation of the charges). The TFT channel width is adjusted such that the current density at the very bottom of the source and drain lines approaches the maximum allowed current density above which electromigration, self-induced heating or any other effects that could lead to degradation becomes critical. This maximises the space that can be occupied by each row of TFTs. As the TFTs in each row are packed as densely as design rules allow, each row has the largest ratio of TFT channel area per overall layout area.

The maximum current density for given source and drain line properties and thickness is normally established experimentally. The accumulated current that flows at the bottom of the source and drain lines depends on the TFT electrical parameters and the driving conditions, and its value can be established experimentally or through simulations using a suitable model, for example a LTPS TFT model for this type of transistor.

The source and drain lines of the first row are connected to the second row of TFTs which has wider source and drain lines, at the expense of the number of TFTs that are connected in parallel. Any cross-overs can be achieved using the gate metal layer. For example, link 36 provides a path between the middle drain region 32 of the second row and the left outer drain region of the top row. Link 37 is for the same purpose.

The TFT width is again adjusted for the second row such that the current density at the bottom of the source and drain lines in this group approaches the maximum value above which degradation sets in. Further groups with decreasing numbers of parallel TFTs are added, until the required overall TFT channel width is reached.

Depending on this width and the given pitch, the final group may consist of merely one TFT, as in the example shown in FIG. 2.

Link 38 also provides a path from the source 30 in the third row to the source on right hand side of the second row. The gate from the third row passes above this link 38 using a section of the source/drain metal.

It can be seen that the configuration can be implemented with only two metal layers—the source/drain metal and the gate metal, and cross overs can be formed using the gate dielectric as cross over insulator.

For each pitch there will be a maximum overall TFT circuit width, and this width is reached when the bottom of the two source and drain lines in the final row consisting of only one TFT has reached its current density maximum.

The principles explained above apply to all other embodiments described below, and for this reason, the further embodiments will be described in less detail.

FIG. 3 shows two of the TFT circuits 40 of FIG. 2 connected in parallel, but arranged on the substrate in back-to-back manner, resulting in twice the current driving capability. Both the top and the bottom source and drain terminals in FIG. 2 have to be connected to external supply lines to guarantee that the current is routed away from the centre of the TFT circuit. The gate connection is in this case at the top or bottom (or both).

FIG. 4 shows a TFT layout in which the source and drain connections are located on opposite sides of the layout.

The source 50 is at the bottom edge of the layout and the drain 52 is at the top. The source and drain metal are fabricated and defined in the same layer and under identical conditions. The poly-Si islands and the source and drain doped regions are omitted for clarity.

This example of transistor circuit has only two rows of transistors, and the transistors of one row have wider source lines but narrower drain lines than the transistors of the other row. The combined source and drain line width is thus constant and there are the same number of transistors in each row.

In FIG. 4, there are two rows of four transistors, with all transistors having the same channel width and channel length, and again all connected electrically in parallel.

With the source connection 50 at the bottom and the drain 52 at the top, the current in the source lines increases moving down the source lines from the top to the bottom. Equally, the drain current increases moving along the drain lines in the opposite direction.

The value a represents the minimum width of the drain lines of TFTs 1 and 4 in the bottom row that is needed to maintain a sufficiently low current density to prevent degradation in these lines at the top edge of TFTs 1 and 4, where the current density in their respective drain lines is largest. As the centre drain line in the bottom row is shared by two TFTs (TFT 2 and 3), its width is doubled to 2a.

The drain lines in the top row are twice as wide as those in the bottom row to accommodate the drain current contribution from both TFT groups. For the same reason, the source lines shared by TFTs 1 and 2 and TFTs 3 and 4 in the bottom row are twice as wide as the corresponding lines in the top row. With this layout, the combined width of all source and drain lines in both rows are equal, at 12a.

It can easily be seen that if the source and drain connections are both located at the top or at the bottom, the combined width of the source and drain lines would have to be 16a within the TFT row having the widest source and drain lines, whilst it would be 8a in the TFT row with the narrowest lines.

The layout with source and drain connections on opposite sides thus reduces the combined line width by 33% from 16a to 12a, which translates into a considerable pitch reduction. An additional benefit of the layout in FIG. 4 is that the maximum current density of the TFTs always occurs at opposite positions of the source and the drain lines. For instance, the source current of TFT 1 in the bottom row is largest at the bottom end of the TFT, but the drain current is largest at the top end. When source and drain connections are at identical sides, the source and drain currents are highest at the same edge, which can result in increased degradation due to self-heating.

The full layout including poly-Si islands and implants is shown in FIG. 5, which shows five semiconductor islands 60.

The layout in FIG. 4 can be extended for TFTs with wider channels by connecting a higher number of TFT rows with decreasing TFT numbers when progressing from the centre of the layout to the bottom and the top. This provides more space available for source and drain lines in the bottom and top regions to accommodate the accumulating current.

FIG. 6 is a schematic example of this configuration. There are two TFT rows with four TFTs, and these are the two middle rows, rows 2 and 3. Assuming each TFT in these rows on its own would require a source and drain line width of a to maintain a sufficiently low current density, the source and drain line widths will be explained for the layout of FIG. 6.

Two additional TFT rows (top and bottom rows—rows 1 and 4) are connected in parallel with two TFTs each whose channel width (the height dimension in the Figure) is twice that of the TFTs in rows 2 and 3. The top row provides the external drain connection and the bottom row provides the source connection.

For clarity, the source and drain connections between the rows are replaced by arrows.

The numbers in FIG. 6 show the line widths.

The drain line width in row 4 has to be 4a as it is shared by two TFTs of width 2W. This line then forks into lines of widths 2⅓ a, 3⅓ a and 2⅓ a in row 3, extending to 3⅓ a, 5⅓ a and 3⅓ a in row 2, and combining to one line of width 16a in row 1.

The two source line widths in row 1 are 2a as they address single TFTs of width 2W. The source line widths increase to 4a, 6a and 8a in rows 2, 3 and 4, respectively.

The sum of all source and drain line widths is 20a in all rows. For very wide TFTs a layout similar to the one shown in FIG. 5 can be used, but with a larger number of TFTs in the two middle rows, reducing to a single TFT at the top and the bottom, and with more intermediate rows.

A number of examples of layout in accordance with the invention have been given above. It will be understood from the discussion above that many other layouts are possible using the principle of the invention.

Although only one specific application of the invention has been shown (in FIG. 1), some other applications have been mentioned, and there are many more applications where TFTs or TFT circuits need to be mounted in an array with limited pitch available.

The invention is of particular benefit for LTPS technology where large transistor channel widths are often needed, but the invention is not limited to this technology. The invention provides an optimisation of the use of the source and drain metal layer to achieve a high density of TFT channel width in a restricted space, and can be applied to other technologies.

Various other modifications will be apparent to those skilled in the art.

1. An array device comprising an array of transistor circuits comprising at least one row of transistor circuits, wherein each transistor circuit comprises a plurality of thin film transistors electrically connected in parallel and provided on a common substrate, the transistors being arranged on the substrate as at least two rows (20₁, 20₂, 20₃) of transistors, wherein the source lines (30) of the transistors in the first and second rows have different widths and the drain lines (32) of the transistors in the first and second rows have different widths, all sources (30) being connected together and all drains (32) being connected together, and wherein a source connection is provided to an end portion of the wider source lines and a drain connection is provided to an end portion of the wider drain lines.

2. A device as claimed in claim 1, wherein the transistors in one row (20₁, 20₂, 20₃) each have the same channel length and channel width, the channel width being perpendicular to the row direction.

3. A device as claimed in claim 1, wherein one (20₁) of the first and second rows of transistors has narrower source and drain lines (30,32) than the other (20₂) of the first and second rows of transistors.

4. A device as claimed in claim 3, wherein there are more transistors in the one row (20₁) than in the other row (20₂).

5. A device as claimed in claim 4, wherein there are twice as many transistors in the one row (20₁) as in the other row (20₂).

6. A device as claimed in claim 3, wherein the transistors in the one row (20₁) have a first channel width and a first channel length, and wherein the transistors in the other row (20₂) have a second, greater channel width and the same, first channel length.

7. A device as claimed in claim 3, wherein the source and drain connections are both at the top or bottom of the transistor circuit.

8. A device as claimed in claim 7, wherein each circuit comprises M rows (20₁, 20₂, 20₃) of transistors, the m^{th} row having k×2^{(m-1)} transistors.

9. A device as claimed in claim 8, wherein M=3, n=1 and k=1, such that there are three rows (20₃, 20₂, 20₁) of transistors with 1, 2 and 4 transistors respectively.

10. A device as claimed in claim 7 wherein each circuit comprises 2M rows of transistors, a top M rows (40) in which the m^{th} row has k×2^{(m-1)} transistors, and a bottom M rows (40) in which in which the m^{th} row has k×2^{(M-m)} transistors.

11. A device as claimed in claim 10, wherein M=3, n=1 and k=1, such that there are a top three rows of transistors with 1, 2 and 4 transistors respectively and a bottom three rows of transistors with 4, 2 and 1 transistors respectively.

12. A device as claimed in claim 10, wherein the transistor circuit is provided with source and drain connections at the top and bottom.

13. A device as claimed in claim 1, wherein the transistors of one of the first and second rows of transistors have a wider source line and a narrower drain line than the transistors of the other of the first and second rows of transistors.

14. A device as claimed in claim 13, wherein there are the same number of transistors in each row (20₁, 20₂, 20₃).

15. A device as claimed in claim 14, wherein each transistor circuit comprises two rows of four transistors.

16. A device as claimed in claim 13, wherein the transistors in each row have the same channel width and channel length.

17. A device as claimed in claim 13, wherein one of the source and drain connections is at the top of the transistor circuit and the other of the source and drain connections is at the bottom of the transistor circuit.

18. A device as claimed in claim 13, wherein a top and bottom row of transistors has n transistors, and one or more middle rows of transistors have 2n transistors.

19. A device as claimed in claim 18, wherein each transistor circuit comprises a top and bottom row of 2 transistors and two middle rows of 4 transistors.

20. A device as claimed in claim 19, wherein the transistors in the middle rows have the same channel length but shorter channel width than the transistors in the top and bottom rows.

21. A device as claimed in claim 1, wherein the channel widths of the transistors in any row are the same, and the channel width is selected such to provide a maximum current density in the source or drain line taking into account the source and drain line widths for the transistors in the row.

22. A device as claimed in claim 1, wherein each circuit occupies a substantially rectangular substrate area.

23. A device as claimed in claim 22, wherein the width of the rectangle is in the range 20-200 μm.

24. A device as claimed in claim 1, wherein the transistors comprise LTPS transistors.

25. A device as claimed in claim 1 comprising an ink jet print head, wherein each circuit is for controlling an ink jet print head print nozzle (12).

26. A device as claimed in claim 1, wherein the transistor circuits are fabricated using a two-metal layer thin film process.
